(19) United States
(12) Patent Application Publication
(10) Pub. No.: US 2026/0255855 A1
(43) Pub. Date: Aug. 27, 2026

(54) DISPLAY PANEL, DISPLAY DEVICE, AND DRIVING METHOD FOR DISPLAY PANEL

(71) Applicants: Chengdu BOE Optoelectronics Technology Co., Ltd., Sichuan Province (CN); BOE Technology Group Co., Ltd., Beijing (CN)

(72) Inventors: Ying HE, Beijing (CN); Kuo SUN, Beijing (CN); Guoqiang TANG, Beijing (CN); Jianbo XIAN, Beijing (CN)

(21) Appl. No.: 18/995,312

(22) PCT Filed: Apr. 17, 2024
(86) PCT No.: PCT/CN2024/088350

§ 371 Date: Jan. 16, 2025

(30) Foreign Application Priority Data
May 24, 2023 (CN) 202310589187.2

(51) Int. Cl. H10K 59/80; G09G 3/3233

(52) U.S. Cl. CPC H10K 59/879; G09G 3/3233; H10K 59/8792; G09G 2300/0452; G09G 2300/0819; G09G 2300/0842; G09G 2300/0857; G09G 2320/045; G09G 2320/0606; G09G 2354/00; G09G 2358/00

(57) ABSTRACT

A display panel, a display device, and a method for driving a display panel are provided. The display panel includes a base substrate, a display structure layer including sub-pixels, and an optical component. The sub-pixel includes: a pixel circuit and a light-emitting element electrically connected to the pixel circuit. The light-emitting element includes: a first light-emitting unit and a second light-emitting unit. The optical component includes: a first optical film layer and a second optical film layer. The refractive index of the second optical film layer is greater than that of the first optical film layer. The first optical film layer is provided with an isolation portion and a plurality of openings. The orthographic projection of the opening on the base substrate at least partially overlaps with the orthographic projection of a light-emitting region of the first light-emitting unit on the base substrate.

### CROSS-REFERENCE TO RELATED APPLICATIONS

This application is a national phase entry under 35 U.S.C. § 371 of International Application No. PCT/CN2024/088350, filed on Apr. 17, 2024, which claims priority to Chinese Patent Application No. 202310589187.2, filed with the China National Intellectual Property Administration on May 24, 2023 and entitled “Display Panel, Display Device and Driving Method for Display Panel”, the entire contents of which are incorporated herein by reference.

### TECHNICAL FIELD

The present disclosure relates to the field of semiconductor technology, and in particular to a display panel, a display device, and a method for driving the display panel.

### BACKGROUND

As electronic products become ubiquitous, while satisfying basic functions of the electronic products, some users have new demands on electronic products based on their own needs. The fast pace of work and life has led to a rapid increase in the frequency of people using electronic products. Sometimes in public places such as subways and offices, we need to reply to messages at any time. The resulting problem is that personal privacy is extremely easy to be exposed.

### SUMMARY

The present disclosure provides a display panel, a display device, and a method for driving the display panel.

The display panel comprises a base substrate, a display structure layer and an optical component.

The display structure layer is located on a side of the base substrate. The display structure layer includes a plurality of sub-pixels. At least one of the plurality of sub-pixels includes: a pixel circuit and a light-emitting element electrically connected to the pixel circuit. The light-emitting element includes: a first light-emitting unit and a second light-emitting unit. A light-emitting region of the first light-emitting unit is isolated from a light-emitting region of the second light-emitting unit.

The optical component is located on the light-emitting side of the display structure layer. The optical component includes: a first optical film layer, and a second optical film layer located on the side of the first optical film layer away from the base substrate. The refractive index of the second optical film layer is greater than the refractive index of the first optical film layer. The first optical film layer is provided with an isolation portion, and a plurality of openings. The orthographic projection of the opening on the base substrate at least partially overlaps with the orthographic projection of the light-emitting region of the first light-emitting unit on the base substrate.

In possible embodiments, the orthographic projection of the isolation portion on the base substrate at least partially covers the orthographic projection of the light-emitting region of the second light-emitting unit on the base substrate.

In possible embodiments, the orthographic projection the isolation portion on the base substrate, at least partially covers the orthographic projection of the first gap between the light-emitting region of the first light-emitting unit and the light-emitting region of the second light-emitting unit on the base substrate, and at least partially covers the orthographic projection of the second gap between different light-emitting elements on the base substrate.

In possible embodiments, the plurality of sub-pixels include: a first sub-pixel emitting a first color light, a second sub-pixel emitting a second color light, and a third sub-pixel emitting a third color light. The light-emitting element of the third sub-pixel and the light-emitting element of the first sub-pixel are sequentially distributed along a first direction. The light-emitting element of the first sub-pixel and the light-emitting element of the second sub-pixel are sequentially distributed in a second direction.

The first light-emitting unit and the second light-emitting unit are distributed in sequence along the second direction.

In possible embodiments, the area of the orthographic projection of the light-emitting region of the first light-emitting unit of at least one light-emitting element on the base substrate is smaller than the area of the orthographic projection of the light-emitting region of the second light-emitting unit of the at least one light-emitting element on the base substrate.

In possible embodiments, a maximum length of a light-emitting region of the first light-emitting unit of at least one light-emitting element in the second direction is smaller than a maximum length of a light-emitting region of the second light-emitting unit of the at least one light-emitting element in the second direction.

In possible embodiments, a maximum length of the first light-emitting unit of at least one light-emitting element in the first direction is smaller than a maximum length of the second light-emitting unit of the at least one light-emitting element in the first direction.

In possible embodiments, a shape of the light-emitting region of the first light-emitting unit of at least one light-emitting element is substantially similar to a shape of the light-emitting region of the second light-emitting unit of the at least one light-emitting element.

In possible embodiments, the light-emitting region of the second light-emitting unit of at least one light-emitting element includes: a second light-emitting main part, and a second light-emitting branch part extending from the second light-emitting main part along the second direction.

The light-emitting region of the first light-emitting unit and the second light-emitting branch part are located on the same side of the second light-emitting main part.

In possible embodiments, a maximum length of the light-emitting region of the first light-emitting unit of at least one light-emitting element in the second direction is smaller than a maximum length of the second light-emitting branch part of the at least one light-emitting element in the second direction.

In possible embodiments, the display panel further includes: a color filter layer located on a side of the optical component away from the base substrate. The color filter layer includes: a plurality of filter units periodically arranged and a black matrix located between adjacent filter units. The plurality of filter units correspond one-to-one to the light-emitting elements of the plurality of sub-pixels.

In possible embodiments, the orthographic projection of the light-emitting region of the first light-emitting unit on the base substrate is a circle. The orthographic projection of the light-emitting region of the second light-emitting unit on the base substrate is a circle.

In possible embodiments, the display structure layer includes an anode layer and multiple light-emitting layers located on the side of the anode layer away from the base substrate. The light-emitting layers of the same light-emitting element have the same light-emitting color, and the light-emitting layers of different light-emitting elements have different light-emitting colors.

In possible embodiments, the display structure layer further includes: a charge transfer layer located between adjacent light-emitting layers.

In possible embodiments, the display panel includes: a plurality of first light-emitting control lines and a plurality of second light-emitting control lines extending along the first direction.

The first light-emitting units in the same light-emitting element row are electrically connected to the same first light-emitting control line, and the second light-emitting units in the same light-emitting element row are electrically connected to the same second light-emitting control line.

In possible embodiments, the display panel further includes: a first light-emitting control connection line, a second light-emitting control connection line, a plurality of first light-emitting control circuits, and a plurality of second light-emitting control circuits.

The plurality of first light-emitting control lines are electrically connected to the first light-emitting control connecting line through the first light-emitting control circuits in one-to-one correspondence. The plurality of second light-emitting control lines are electrically connected to the second light-emitting control connecting line through the second light-emitting control circuits in one-to-one correspondence.

The first light-emitting control circuit is configured to provide a signal of the first light-emitting control connection line to the first light-emitting control line according to the light-emitting sub-pixel. The second light-emitting control circuit is configured to provide a signal of the second light-emitting control connection line to the second light-emitting control line according to the light-emitting sub-pixel.

In possible embodiments, the pixel circuit at least includes: a data writing sub-circuit, a storage sub-circuit, a driving sub-circuit and a control sub-circuit.

The data writing sub-circuit is electrically connected to the data line, the scan line and the driving sub-circuit, and is configured to provide the driving sub-circuit with a data signal transmitted by the data line under the control of the scan line.

The driving sub-circuit is electrically connected to the data writing sub-circuit, the storage sub-circuit, the control sub-circuit and the first light-emitting unit of the light-emitting element, and is configured to drive the first light-emitting unit to emit light under the control of the data signal.

The control sub-circuit is electrically connected to the second light-emitting control line, the driving sub-circuit, the first light-emitting unit and the second light-emitting unit of the light-emitting element, and is configured to control the second light-emitting unit to emit light together with the first light-emitting unit under the control of the second light-emitting control line.

In possible embodiments, the control sub-circuit includes: a first control transistor. A gate of the first control transistor is electrically connected to the second light-emitting control line, a first electrode of the first control transistor is electrically connected to the driving sub-circuit, and a second electrode of the first control transistor is electrically connected to the second light-emitting unit.

In possible embodiments, the control sub-circuit further includes: a second control transistor. A gate of the second control transistor is electrically connected to a second reset control line, a first electrode of the second control transistor is electrically connected to a second initial signal line, and a second electrode of the second control transistor is electrically connected to the second light-emitting unit.

Embodiments of the present disclosure further provide a display device, which includes the display panel provided by the embodiments of the present disclosure.

Embodiments of the present disclosure further provide a method for driving the display panel provided in the embodiments of the present disclosure, which includes:
In response to determining to display in the anti-peeping display mode, controlling the pixel electrode to drive the first light-emitting unit of the light-emitting element to emit light;
In response to determining to display in the sharing display mode, controlling the pixel electrode to drive the first light-emitting unit and the second light-emitting unit of the light-emitting unit to emit light simultaneously.

### BRIEF DESCRIPTION OF DRAWINGS

FIG. 1 is a schematic structural diagram of a display panel according to at least one embodiment of the present disclosure.

FIG. 2 is a schematic diagram of a planar structure of a display panel according to at least one embodiment of the present disclosure.

FIG. 3A is a schematic diagram of a planar structure of a sub-pixel of a display panel according to at least one embodiment of the present disclosure.

FIG. 3B is a schematic diagram of a planar structure of a sub-pixel of a display panel according to at least one embodiment of the present disclosure.

FIG. 3C is a schematic diagram of a planar structure of a sub-pixel of a display panel according to at least one embodiment of the present disclosure.

FIG. 4 is a schematic diagram of a pixel circuit according to at least one embodiment of the present disclosure.

FIG. 5 is an equivalent circuit diagram of a pixel circuit according to at least one embodiment of the present disclosure.

FIG. 6 is a schematic diagram of the connection of sub-pixels according to at least one embodiment of the present disclosure.

FIG. 7 is a first example of a partial cross-sectional view along the Q-Q′ direction in FIG. 3A.

FIG. 8 is a second example of a partial cross-sectional view along the Q-Q′ direction in FIG. 3A.

FIG. 9 is a third example of a partial cross-sectional view along the Q-Q′ direction in FIG. 3A.

FIG. 10 is a partial enlarged schematic diagram of FIG. 9.

FIG. 11 is a first schematic diagram of light emission of the cross-sectional structure along the Q-Q′ direction in FIG. 3A.

FIG. 12 is a second schematic diagram of light emission of the cross-sectional structure along the Q-Q′ direction in FIG. 3A.

FIG. 13 is a schematic flow chart of a method for driving a display panel provided in an embodiment of the present disclosure.

FIG. 14 is a schematic diagram of a display device provided in an embodiment of the present disclosure.

### DETAILED DESCRIPTION

In order to make the purpose, technical solution and advantages of the embodiments of the present disclosure more clear, the technical solution of the embodiments of the present disclosure will be clearly and completely described below in conjunction with the drawings of the embodiments of the present disclosure. Obviously, the described embodiments are only part of the embodiments of the present disclosure, rather than all the embodiments. Based on the described embodiments of the present disclosure, all other embodiments obtained by ordinary technicians in the field without creative work are within the scope of protection of the present disclosure.

Unless otherwise defined, technical or scientific terms used in the present disclosure should have the common meanings understood by a person having ordinary skills in the field to which the present disclosure belongs. The terms “first”, “second” and the like used in the present disclosure do not indicate any order, quantity or importance, but are only used to distinguish different components. The words “include” or “comprise” and the like mean that the elements or objects preceding the word include the elements or objects listed after the word and their equivalents, but do not exclude other elements or objects. The words “connect” or “connected” and the like are not limited to physical or mechanical connections, but may include electrical connections, whether direct or indirect. “Up”, “down”, “left”, “right”, etc. are only used to indicate relative position relationships. When the absolute position of the object being described changes, the relative position relationship may also change accordingly.

As used herein, “about” or “substantially the same” is inclusive of the stated value and means within an acceptable range of deviation for the value as determined by one of ordinary skill in the art taking into account the measurements in question and errors associated with the measurement for the particular value (i.e., the limitations of the measurement system). For example, “substantially the same” may mean within one or more standard deviations, or within ±30%, 20%, 10%, 5% relative to the stated value.

In the drawings, the thickness of layers, films, panels, regions, etc., are exaggerated for clarity. Exemplary embodiments are described herein with reference to cross-section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shapes of the regions and are not intended to limit the scope of the present claims.

In order to keep the following description of the embodiments of the present disclosure clear and concise, the present disclosure omits detailed descriptions of well-known functions and well-known components.

In traditional solutions, an external privacy film is used for privacy protection. These solutions have the problem of low display brightness, which can easily cause visual fatigue. In addition, in order to achieve appropriate display brightness, power consumption is often increased. Moreover, if you need to switch the anti-peeping state to the shared state for display, you need to tear off the anti-peeping film, which increases the risk of damage to the screen and cannot be switched freely.

Embodiments of the present disclosure provide a display panel, including: a base substrate, a display structure layer, and an optical component.

The display structure layer is located on a side of the base substrate. The display structure layer includes a plurality of sub-pixels. At least one of the plurality of sub-pixels includes: a pixel circuit and a light-emitting element electrically connected to the pixel circuit. The light-emitting element includes: a first light-emitting unit and a second light-emitting unit. A light-emitting region of the first light-emitting unit and a light-emitting region of the second light-emitting unit are isolated from each other. The pixel circuit is configured to drive at least one of the first light-emitting unit and the second light-emitting unit to emit light according to a display mode.

The optical component is located on the light-emitting side of the display structure layer. The optical component includes: a first optical film layer, and a second optical film layer located on a side of the first optical film layer away from the base substrate. The refractive index of the second optical film layer is greater than the refractive index of the first optical film layer. The first optical film layer has an isolation portion, and a plurality of openings. The orthographic projections of the openings on the base substrate at least partially overlap with the orthographic projection of the light-emitting region of the first light-emitting unit on the base substrate.

The display panel provided by embodiments of the present disclosure realizes different display modes by dividing the light-emitting element of the sub-pixel into two light-emitting units (i.e., the first light-emitting unit and the second light-emitting unit), and controlling the light emission of the first light-emitting unit and the second light-emitting unit through the pixel circuit, and improves the problem of low display brightness in traditional solutions in which privacy filter is used for anti-peeping display. The low display brightness is easy to cause visual fatigue. The anti-peeping film needs to be torn off when the anti-peeping display is not needed, which has a high risk of damaging the screen. In addition, in embodiments of the present disclosure, an optical component is arranged on the light-emitting side of the display structure layer. The optical component includes: a first optical film layer, and a second optical film layer located on the side of the first optical film layer away from the base substrate. The refractive index of the second optical film layer is greater than the refractive index of the first optical film layer. The first optical film layer has an isolation portion and a plurality of openings. In the anti-peeping display mode, when the light path is incident on the side wall of the opening, a total reflection is formed at the interface between the first optical film layer and the second optical film layer, so that the light path converges inward, the viewing angle is narrowed, and the light extraction efficiency is increased, which can improve the problem that the light-emitting region is reduced and the brightness is reduced when the light-emitting element is divided into the first light-emitting unit and the second light-emitting unit, and the problem that increasing current is required when the required brightness is constant, leading to a reduction in the life of the display panel.

In some exemplary embodiments, the display panel may be an organic light-emitting diode (OLED) display panel, or may be a quantum dot light-emitting diode (QLED) display panel, or may be a plasma display device (PDP) display panel, or may be an electrophoretic display (EPD) display panel. The embodiments are not limited to these.

In some example embodiments, the display panel may include an anti-peeping display mode and a sharing display mode. The anti-peeping display mode can meet the user's display needs for privacy protection, and the sharing display mode can meet the user's display needs in information sharing scenarios. In some examples, the display panel may be provided with a switch button. The user switches the display mode of the display panel by pressing the switch button. However, the embodiments are not limited to this. In other examples, a triggering method such as voice control or induction may be used to initiate the switching of the display modes of the display panel.

In some exemplary embodiments, the display mode may include a first display mode and a second display mode. The pixel circuit may be configured to drive only the first light-emitting unit to emit light in the first display mode (e.g., an anti-peeping display mode), and to drive the second light-emitting unit to emit light together with the first light-emitting unit in the second display mode (e.g., a sharing display mode). In other examples, the pixel circuit may be configured to drive only the second light-emitting unit to emit light in a first display mode (e.g., an anti-peeping display mode), and to drive the second light-emitting unit to emit light together with the first light-emitting unit in a second display mode (e.g., a sharing display mode). However, the embodiments are not limited to these.

The solution of the embodiments is described below by means of some examples.

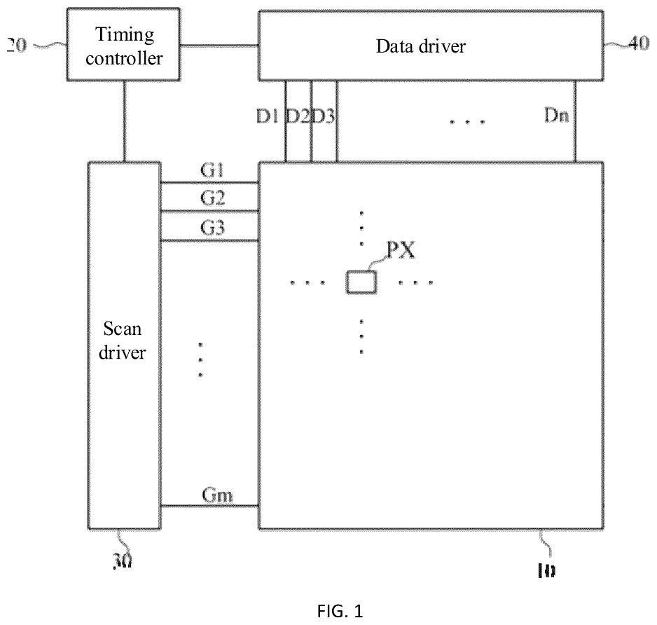

FIG. 1 is a schematic structural diagram of a display panel according to at least one embodiment of the present disclosure. In some examples, as shown in FIG. 1, the display panel may include: a timing controller 20, a data driver 40, a gate driving circuit, and a sub-pixel array 10. The gate driving circuit may include at least one driver, for example, a scan driver 30. The timing controller 20, the data driver 40, and the gate driving circuit may be located in a peripheral area outside the display area of the display panel. The sub-pixel array 10 located in the display area may include a plurality of sub-pixels PX arranged regularly. The scan driver 30 may be configured to provide a scan signal to the sub-pixel PX along a scan line. The data driver 40 may be configured to provide a data signal to the sub-pixel PX along a data line. The timing controller 20 may be configured to control the scan driver 30 and the data driver 40.

In some examples, the timing controller 20 may provide grayscale values and control signals suitable for the specifications of the data driver 40 to the data driver 40. The timing controller 20 may provide clock signals, initial signals, etc. suitable for the specifications of the scan driver 30 to the scan driver 30. The data driver 40 may generate data voltages to be supplied to the data lines D1 to Dn by using the grayscale value and the control signal received from the timing controller 20. For example, the data driver 40 may sample a grayscale value using a clock signal and apply a data signal corresponding to the grayscale value to the data lines D1 to Dn in units of sub-pixel rows. The scan driver 30 may generate scan signals to be supplied to the scan lines G1 to Gm by using a clock signal, an initial signal, etc. received from the timing controller 20. For example, the scan driver 30 may sequentially supply a scan signal having on-level pulses to the scan lines. In some examples, the scan driver 30 may include a shift register, and may generate a scan signal in a manner of sequentially transmitting a scan initial signal provided in the form of on-level pulses to a next stage circuit under the control of a clock signal. n and m are both natural numbers.

In some examples, the gate driving circuit can be disposed directly on the base substrate. For example, the gate driver may be disposed in the peripheral regions on the left and right sides of the display area. In some examples, the gate driver may be formed together with the sub-pixels in a process of forming the sub-pixels. However, the embodiments do not limit the location or formation method of the gate driver. In some examples, the gate driver may be disposed on a separate chip or a printed circuit board to connect to pads or solder pads formed on the base substrate.

In some examples, the data driver 40 may be disposed on a separate chip or a printed circuit board to be connected to the sub-pixels PX through signal access pins disposed on the base substrate. For example, the data driver 40 may be formed using a chip on glass, a chip on plastic, a chip on film, etc. to connect to signal access pins on the base substrate. The timing controller 20 may be provided separately from the data driver 40 or integrally provided with the data driver 40. However, the embodiments are not limited to these.

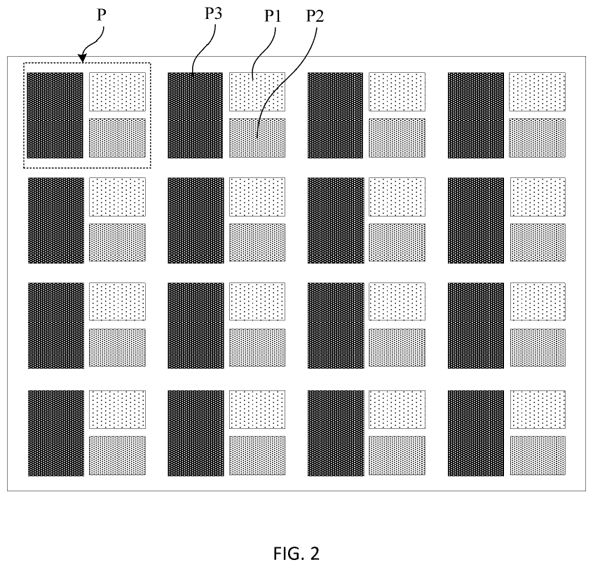

FIG. 2 is a schematic diagram of a planar structure of a display panel according to at least one embodiment of the present disclosure. In some examples, as shown in FIG. 2, the display area of the display panel may include a plurality of pixel units P arranged in a matrix manner. At least one of the plurality of pixel units P may include a first sub-pixel P1 emitting a first color light, a second sub-pixel P2 emitting a second color light, and a third sub-pixel P3 emitting a third color light. For example, the first color light may be red light, the second color light may be green light, and the third color light may be blue light. In other words, the first sub-pixel P1 may be a red (R) sub-pixel, the second sub-pixel P2 may be a green (G) sub-pixel, and the third sub-pixel P3 may be a blue (B) sub-pixel. In some other examples, the pixel unit P may include four sub-pixels, for example, a red sub-pixel, a green sub-pixel, a blue sub-pixel, and a white sub-pixel. However, the present disclosure is not limited thereto.

In some examples, the shape of the sub-pixels in the pixel unit P may be rectangular, diamond, pentagonal, or hexagonal. As shown in FIG. 2, the shape of the sub-pixels in the pixel unit P is rectangular. For example, when the pixel unit P includes three sub-pixels, the three sub-pixels can be arranged horizontally, vertically or in a triangular pattern. When the pixel unit includes four sub-pixels, the four sub-pixels can be arranged horizontally, vertically or in a square pattern. However, the present disclosure is not limited thereto.

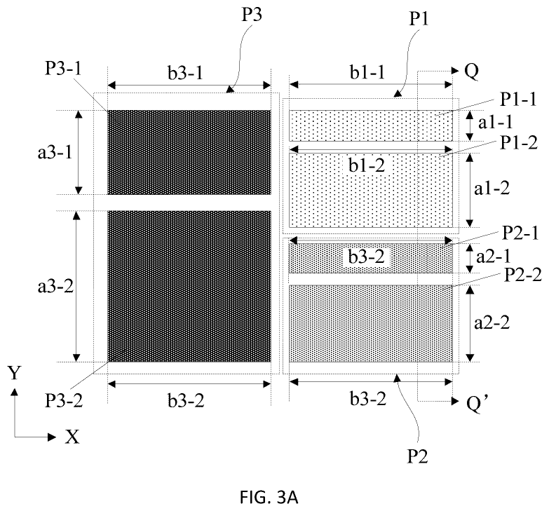

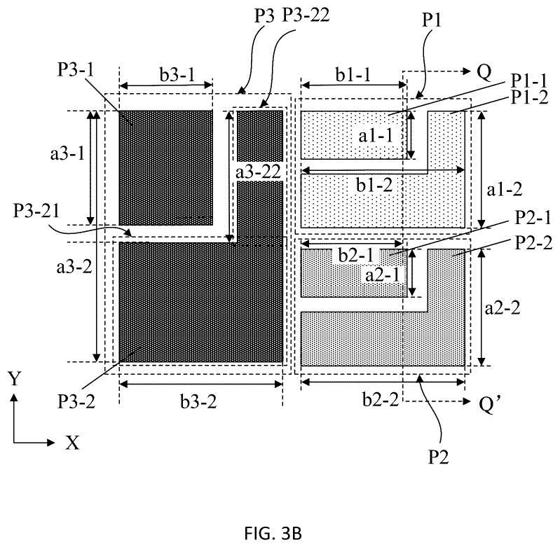

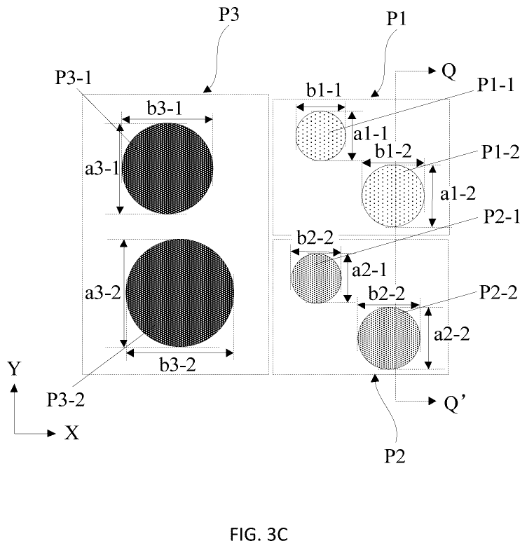

In some examples, as shown in FIGS. 3A, 3B and 3C, the light-emitting element of the third sub-pixel P3 and the light-emitting element of the second sub-pixel P2 are sequentially distributed along the first direction X. The light-emitting element of the first sub-pixel P1 and the light-emitting element of the second sub-pixel P2 are sequentially distributed along the second direction Y. The first direction X and the second direction Y may be located in the same plane and intersect with each other, for example, the first direction X may be perpendicular to the second direction Y.

In some examples, as shown in FIGS. 3A, 3B, and 3C, the light-emitting element of at least one sub-pixel may be divided into two light-emitting units along the second direction Y. For example, the light-emitting element of the first sub-pixel P1 may include: a first light-emitting unit P1-1 and a second light-emitting unit P1-2 arranged along the second direction Y. The light-emitting element of the second sub-pixel P2 may include: a first light-emitting unit P2-1 and a second light-emitting unit P2-2 arranged along the second direction Y. The light-emitting element of the third sub-pixel P3 may include: a first light-emitting unit P3-1 and a second light-emitting unit P3-2 arranged along the second direction Y.

In some examples, as shown in FIG. 3A, FIG. 3B, and FIG. 3C, in the first direction X, the first light-emitting units P1-1, P2-1, and P3-1 may serve as a pixel unit P, and a plurality of pixel units P are sequentially arranged along the first direction X to form a row.

In some examples, as shown in FIG. 3A, FIG. 3B, and FIG. 3C, the first light-emitting unit and the second light-emitting unit are sequentially distributed along the second direction Y. For example, in the first sub-pixel P1, in the second direction Y, the first light-emitting unit P1-1 and the second light-emitting unit P1-2 can be arranged at intervals. In the second sub-pixel P2, in the second direction Y, the first light-emitting unit P2-1 and the second light-emitting unit P2-2 can be arranged at intervals. In the third sub-pixel P3, in the second direction Y, the first light-emitting unit P3-1 and the second light-emitting unit P3-2 can be arranged at intervals.

In some examples, the light-emitting region of at least one light-emitting element may include a light-emitting region of a first light-emitting unit of the light-emitting element and a light-emitting region of a second light-emitting unit of the light-emitting element. The light-emitting region of the first light-emitting unit of the at least one light-emitting element and the light-emitting region of the second light-emitting unit of the at least one light-emitting element may be isolated from each other.

In some examples, an area of the orthographic projection of the light-emitting region of the first light-emitting unit on the base substrate is smaller than an area of the orthographic projection of the light-emitting region of the second light-emitting unit on the base substrate. For example, as shown in FIGS. 3A, 3B and 3C, in the first sub-pixel P1, the area of the orthographic projection of the light-emitting region of the first light-emitting unit P1-1 on the base substrate is smaller than the area of the orthographic projection of the light-emitting region of the second light-emitting unit P1-2 on the base substrate. For example, as shown in FIGS. 3A, 3B and 3C, in the second sub-pixel P2, the area of the orthographic projection of the light-emitting region of the first light-emitting unit P2-1 on the base substrate is smaller than the area of the orthographic projection of the light-emitting region of the second light-emitting unit P2-2 on the base substrate. For example, as shown in FIGS. 3A, 3B and 3C, in the third sub-pixel P3, the area of the orthographic projection of the light-emitting region of the first light-emitting unit P2-1 on the base substrate is smaller than the area of the orthographic projection of the light-emitting region of the second light-emitting unit P3-2 on the base substrate. In embodiments of the present disclosure, due to the provision of the optical component, in the anti-peeping display mode, the screen brightness is relatively high, so that in the condition that the light-emitting region of the first light-emitting unit on the base substrate is smaller than the light-emitting region of the second light-emitting unit on the base substrate, and the brightness requirements are the same, the power consumption of the display panel can be reduced.

In some examples, in sub-pixels, the ratio of the area of the orthographic projection of the light-emitting region of the first light-emitting unit on the base substrate to the area of the orthographic projection of the light-emitting region of the second light-emitting unit on the base substrate is not completely equal. For example: as shown in FIGS. 3A, 3B, and 3C, in the first sub-pixel P1, the ratio of the area of the orthographic projection of the light-emitting region of the first light-emitting unit P1-1 on the base substrate to the area of the orthographic projection of the light-emitting region of the second light-emitting unit P1-2 on the base substrate is R1, and R1 is 0.10 to 0.80. In the second sub-pixel P2, the ratio of the area of the orthographic projection of the light-emitting region of the first light-emitting unit P2-1 on the base substrate to the area of the orthographic projection of the light-emitting region of the second light-emitting unit P2-2 on the base substrate is R2, and R2 is 0.15 to 0.8. In the third sub-pixel P3, the ratio of the area of the orthographic projection of the light-emitting region of the first light-emitting unit P3-1 on the base substrate to the area of the orthographic projection of the light-emitting region of the second light-emitting unit P3-2 on the base substrate is R3, and R3 is 0.30 to 0.85. Such a design is beneficial in ensuring an appropriate ratio of light-emitting areas in sub-pixels of different colors in the anti-peeping state, avoiding problems such as color deviation.

In some examples, as shown in FIG. 3A, R1≤R2<R3, or R1<R2<R3.

In some examples, the area of the light-emitting region of the first light-emitting unit of at least one light-emitting element and the area of the light-emitting region of the second light-emitting unit of the at least one light-emitting element may be substantially the same.

In some examples, as shown in FIG. 3A and FIG. 3C, the shape of the light-emitting region of the first light-emitting unit of at least one light-emitting element is substantially similar to the shape of the light-emitting region of the second light-emitting unit of the at least one light-emitting element. For example, the shape of the light-emitting region of the first light-emitting unit and the shape of the light-emitting region of the second light-emitting unit can both be rectangular, circular, triangular, trapezoidal, pentagonal, hexagonal or octagonal. For example, however, the embodiments are not limited to these. For example, the shapes of two light-emitting units of at least one light-emitting element may also be different.

In some examples, as shown in FIGS. 3A and 3C, a maximum length of a light-emitting region of a first light-emitting unit of at least one light-emitting element in the second direction is smaller than a maximum length of a light-emitting region of a second light-emitting unit of the at least one light-emitting element in the second direction. For example, in the first sub-pixel P1, the maximum length a1-1 of the light-emitting region of the first light-emitting unit P1-1 in the second direction Y is smaller than the maximum length a1-2 of the light-emitting region of the second light-emitting unit P1-2 in the second direction. For example, in the second sub-pixel P2, the maximum length a2-1 of the light-emitting region of the first light-emitting unit P2-1 in the second direction Y is smaller than the maximum length a2-2 of the light-emitting region of the second light-emitting unit P2-2 in the second direction. For example, in the third sub-pixel P3, the maximum length a3-1 of the light-emitting region of the first light-emitting unit P3-1 in the second direction Y is smaller than the maximum length a3-2 of the light-emitting region of the third light-emitting unit P3-2 in the second direction.

In some examples, a maximum length of a first light-emitting unit of at least one light-emitting element in the first direction is smaller than a maximum length of a second light-emitting unit of the at least one light-emitting element in the first direction. For example, as shown in FIGS. 3B and 3C, in the first sub-pixel P1, the maximum length b1-1 of the light-emitting region of the first light-emitting unit P1-1 in the first direction X is smaller than the maximum length b1-2 of the light-emitting region of the second light-emitting unit P1-2 in the first direction X. For example, as shown in FIGS. 3B and 3C, in the second sub-pixel P2, the maximum length b2-1 of the light-emitting region of the first light-emitting unit P2-1 in the first direction X is smaller than the maximum length b2-2 of the light-emitting region of the second light-emitting unit P2-2 in the first direction X. For example, as shown in FIGS. 3B and 3C, in the third sub-pixel P3, the maximum length b3-1 of the light-emitting region of the first light-emitting unit P3-1 in the first direction X is smaller than the maximum length b3-2 of the light-emitting region of the third light-emitting unit P3-2 in the first direction X.

In some examples, the maximum length of the first light-emitting unit of at least one light-emitting element in the first direction may also be equal to the maximum length of the second light-emitting unit of the at least one light-emitting element in the first direction. For example, as shown in FIG. 3A, in the first sub-pixel P1, the maximum length b1-1 of the light-emitting region of the first light-emitting unit P1-1 in the first direction X is equal to the maximum length b1-2 of the light-emitting region of the second light-emitting unit P1-2 in the first direction X. For example, as shown in FIG. 3A, in the second sub-pixel P2, the maximum length b2-1 of the light-emitting region of the first light-emitting unit P2-1 in the first direction X is equal to the maximum length b2-2 of the light-emitting region of the second light-emitting unit P2-2 in the first direction X. For example, as shown in FIG. 3A, in the third sub-pixel P3, the maximum length b3-1 of the light-emitting region of the first light-emitting unit P3-1 in the first direction X is equal to the maximum length b3-2 of the light-emitting region of the third light-emitting unit P3-2 in the first direction X.

In some examples, the second light-emitting unit of at least one light-emitting element is located on both sides or around the first light-emitting unit of the at least one light-emitting element.

In some examples, the light-emitting region of the second light-emitting unit of at least one light-emitting element includes: a second light-emitting main part, and a second light-emitting branch part extending from the second light-emitting main part along a second direction. The light-emitting region of the first light-emitting unit and the second light-emitting branch part are located on the same side of the second light-emitting main part. For example, as shown in FIG. 3B, in the third sub-pixel P3, the light-emitting region of the second light-emitting unit P3-2 includes: a second light-emitting main part P3-21, and a second light-emitting branch part P3-22 extending from the second light-emitting main part P3-21 along the second direction Y. The light-emitting region of the first light-emitting unit P3-1 and the second light-emitting branch part P3-22 are located on the same side of the second light-emitting main part P3-21.

In some examples, a maximum length of a light-emitting region of a first light-emitting unit of at least one light-emitting element in the second direction is smaller than a maximum length of a second light-emitting branch part of the at least one light-emitting element in the second direction. For example, as shown in FIG. 3B, in the third sub-pixel P3, the maximum length a3-1 of the light-emitting region of the first light-emitting unit P3-1 in the second direction Y is smaller than the maximum length a3-22 of the second light-emitting branch part P3-22 in the second direction Y. In some embodiments, the maximum length of the light-emitting region of the first light-emitting unit of at least one light-emitting element in the second direction may also be equal to the maximum length of the second light-emitting branch of the at least one light-emitting element in the second direction.

In some examples, the area of the light-emitting region of the third sub-pixel P3 may be greater than the area of the light-emitting region of the second sub-pixel P2. The area of the light-emitting region of the second sub-pixel P2 may be greater than the area of the light-emitting region of the first sub-pixel P1. Specifically, the area of the light-emitting region of the first sub-pixel P1: the area of the light-emitting region of the second sub-pixel P2: the area of the light-emitting region of the third sub-pixel P3 may be 1:(1¹⁸ 1.5):(1.2^{~}2.5).

In some examples, as shown in FIG. 3A, a distance between a light-emitting region of the second light-emitting unit P1-2 of the first sub-pixel P1 and a light-emitting region of the second light-emitting unit P2-2 of the second sub-pixel P2 may be 15 μm to 30 μm.

In some embodiments, referring to FIG. 3A, in the first sub-pixel P1, the minimum spacing between the light-emitting region of the first light-emitting unit P1-1 and the light-emitting region of the second light-emitting unit P1-2 may be d1. In the second sub-pixel P2, the minimum spacing between the light-emitting region of the first light-emitting unit P2-1 and the light-emitting region of the second light-emitting unit P2-2 may be d2. In the third sub-pixel P3, the minimum spacing between the light-emitting region of the first light-emitting unit P3-1 and the light-emitting region of the second light-emitting unit P3-2 may be d3. For example, d1=d2=d3. Specifically, the range of d1, d2, and d3 may be 1.0 μm to 4.0 μm.

In some embodiments, as shown in FIG. 7, the ratio of the area of the light-emitting region of the second light-emitting unit to the area of the isolation portion 1052 may be in the range of 10% to 35%.

In some examples, at least one sub-pixel may include pixel circuit and a light-emitting element. For example, the first sub-pixel P1, the second sub-pixel P2, and the third sub-pixel P3 may each include a pixel circuit and a light-emitting element. In some examples, the pixel circuit may include multiple transistors and at least one capacitor. For example, the pixel circuit may be a 3T1C structure, a 7T1C structure, a 5T1C structure, an 8T1C structure, or an 8T2C structure, etc. In the above structures of the pixel circuit, T refers to a thin film transistor, C refers to a capacitor, the number before T represents the number of thin film transistors in the circuit, and the number before C represents the number of capacitors in the circuit.

In some examples, the light-emitting elements in the first sub-pixel P1, the second sub-pixel P2, and the third sub-pixel P3 are respectively connected to the pixel circuits of the sub-pixels. The light-emitting elements can be configured to emit light of corresponding brightness in response to the driving current output by the pixel circuits of the sub-pixels. For example, the light-emitting element may be an organic light-emitting diode (OLED), which may include a stacked first electrode (anode), an organic light-emitting layer, and a second electrode (cathode). However, the embodiments are not limited to these. For example, the light-emitting element may be a micro light-emitting diode (Micro-LED), a mini diode (Mini-LED), or a quantum dot light-emitting diode (QLED).

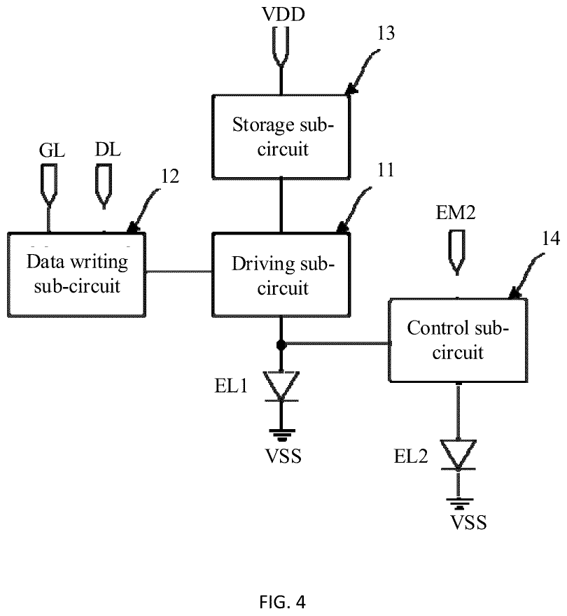

FIG. 4 is a schematic diagram of a pixel circuit according to at least one embodiment of the present disclosure. In some examples, as shown in FIG. 4, the pixel circuit may include at least: a driving sub-circuit 11, a data writing sub-circuit 12, a storage sub-circuit 13, and a control sub-circuit 14. The data writing sub-circuit 12 may be electrically connected to the scan line GL, the data line DL and the driving sub-circuit 11, and configured to provide the driving sub-circuit 11 with a data signal transmitted by the data line DL under the control of the scan line GL. The driving sub-circuit 11 may be electrically connected to the storage sub-circuit 13, the data writing sub-circuit 12, the control sub-circuit 14 and the first light-emitting unit EL1, and configured to drive the first light-emitting unit EL1 to emit light. The storage sub-circuit 13 may be electrically connected to the driving sub-circuit 11 and the first power line VDD. The control sub-circuit 14 may be electrically connected to the second light-emitting control line EM2, the driving sub-circuit 11, the first light-emitting unit EL1 and the second light-emitting unit EL2, and configured to control the second light-emitting unit EL2 to emit light together with the first light-emitting unit EL1 under the control of the second light-emitting control line EM2.

In some examples, the first light-emitting unit EL1 may include a first anode, a first organic light-emitting layer, and a first cathode that are stacked. The second light-emitting unit EL2 may include a second anode, a second organic light-emitting layer, and a second cathode that are stacked. The first anode of the first light-emitting unit EL1 may be electrically connected to the driving sub-circuit 11 and the control sub-circuit 14, and the first cathode may be electrically connected to the second power line VSS. The second anode of the second light-emitting unit EL2 may be electrically connected to the control sub-circuit 14, and the second cathode of the second light-emitting unit EL2 may be electrically connected to the second power line VSS.

In some examples, the first power line VDD may be configured to continuously provide a first voltage signal of a high level, and the second power line VSS may be configured to continuously provide a second voltage signal of a low level. The first voltage signal is greater than the second voltage signal.

In some examples, the gate driving circuit disposed in the peripheral area of the display panel may include: a first scan driver and a second scan driver. The first scan driver may be configured to provide a first scan signal to the first scan line, and the second scan driver may be configured to provide a second scan signal to the second scan line.

In some examples, a plurality of transistors of the pixel circuit may adopt low-temperature polysilicon thin film transistors, or may adopt oxide thin film transistors, or may adopt low-temperature polysilicon thin film transistors and oxide thin film transistors. The active layer of the low temperature polysilicon thin film transistor uses low temperature polysilicon (LTPS), and the active layer of the oxide thin film transistor uses oxide. Low-temperature polysilicon thin-film transistors have the advantages of high mobility and fast charging, while oxide thin-film transistors have the advantages of low leakage current. In some examples, low-temperature polysilicon thin-film transistors and oxide thin-film transistors can be integrated on a display panel to form a low-temperature polycrystalline oxide display panel, which can take advantage of the advantages of both to achieve high resolution (PPI, Pixel Per Inch) and low-frequency driving, reduce power consumption, and improve display quality. However, the embodiments are not limited to these.

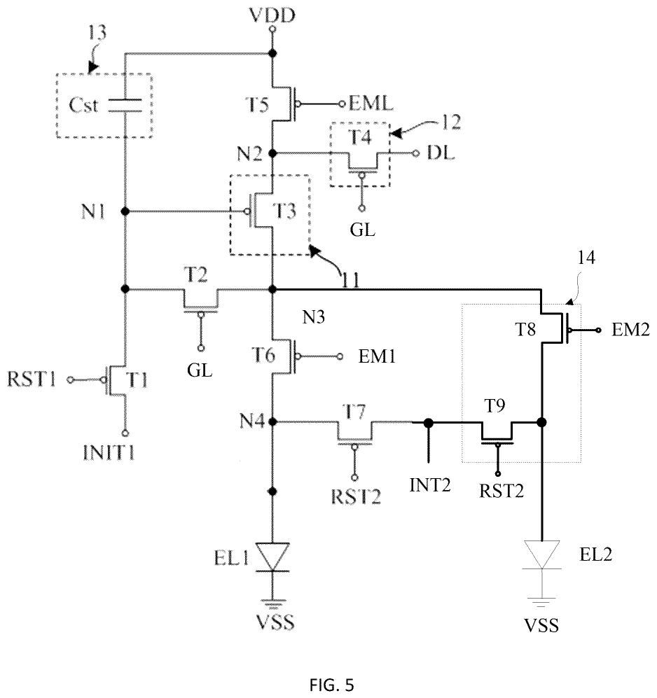

FIG. 5 is an equivalent circuit diagram of a pixel circuit according to at least one embodiment of the present disclosure. In some examples, as shown in FIG. 5, the pixel circuit may be a 9T1C structure. The driving sub-circuit 11 may include a driving transistor T3. The data writing sub-circuit 12 may include a data writing transistor T4. The storage sub-circuit 13 may include a storage capacitor Cst. The control sub-circuit 14 may include a first control transistor T8. The gate of the first control transistor T8 is electrically connected to the second light-emitting control line EM2. The first electrode of the first control transistor T8 is electrically connected to the driving sub-circuit 11. The second electrode of the first control transistor T8 is electrically connected to the second light-emitting unit EL2. The pixel circuit may further include: a first reset transistor T1, a second reset transistor T7, a threshold compensation transistor T2, a first light-emitting control transistor T5, and a second light-emitting control transistor T6.

In some embodiments, as shown in FIG. 5, the control sub-circuit 14 further includes: a second control transistor T9. The gate of the second control transistor T9 is electrically connected to the second reset control line RST2, the first electrode of the second control transistor T9 is electrically connected to the second initial signal line INT2, and the second electrode of the second control transistor T9 is electrically connected to the second light-emitting unit EL2.

In some examples, as shown in FIG. 5, a gate of the first reset transistor T1 is electrically connected to the first reset control line RST1, a first electrode of the first reset transistor T1 is electrically connected to the first initial signal line INIT1, and a second electrode of the first reset transistor T1 is electrically connected to the first node N1. A gate of the threshold compensation transistor T2 is electrically connected to the scan line GL, a first electrode of the threshold compensation transistor T2 is electrically connected to the first node N1, and a second electrode of the threshold compensation transistor T2 is electrically connected to the third node N3. A gate electrode of the driving transistor T3 is electrically connected to the first node N1, a first electrode of the driving transistor T3 is electrically connected to the second node N2, and a second electrode of the driving transistor T3 is electrically connected to the third node N3. A gate electrode of the data writing transistor T4 is electrically connected to the scan line GL, a first electrode of the data writing transistor T4 is electrically connected to the data line DL, and a second electrode of the data writing transistor T4 is electrically connected to the second node N2. A gate of the first light-emitting control transistor T5 is electrically connected to the light-emitting control line EML, a first electrode of the first light-emitting control transistor T5 is electrically connected to the first power supply line VDD, and a second electrode of the first light-emitting control transistor T5 is electrically connected to the second node N2. A gate of the second light-emitting control transistor T6 is electrically connected to the first light-emitting control line EM1, a first electrode of the second light-emitting control transistor T6 is electrically connected to the third node N3, and a second electrode of the second light-emitting control transistor T6 is electrically connected to the fourth node N4. A gate of the second reset transistor T7 is electrically connected to the second reset control line RST2, a first electrode of the second reset transistor T7 is electrically connected to the second initial signal line INIT2, and a second electrode of the second reset transistor T7 is electrically connected to the fourth node N4. A gate of the first control transistor T8 is electrically connected to the second light-emitting control line EM2, a first electrode of the first control transistor T8 is electrically connected to the third node N3, and a second electrode of the first control transistor T8 is electrically connected to the second anode of the second light-emitting unit EL2. A first electrode plate of the storage capacitor Cst is electrically connected to the first node N1, and a second electrode plate of the storage capacitor Cst is electrically connected to the first power line VDD. A first anode of the first light-emitting unit EL1 is electrically connected to the fourth node N4, and a first cathode of the first light-emitting unit EL1 is electrically connected to the second power line VSS. A second anode of the second light-emitting unit EL2 is electrically connected to the second electrode of the first control transistor T8, and a second cathode of the second light-emitting unit EL2 is electrically connected to the second power line VSS.

In some examples, the first node N1 is a connection point of the first reset transistor T1, the threshold compensation transistor T2, the driving transistor T3, and the storage capacitor Cst. The second node N2 is a connection point of the driving transistor T3, the data writing transistor T4, and the first light-emitting control transistor T5. The third node N3 is a connection point of the driving transistor T3, the threshold compensation transistor T2, the first control transistor T8, and the second light-emitting control transistor T6. The fourth node N4 is a connection point of the second light-emitting control transistor T6, the second reset transistor T7, and the first anode of the first light-emitting unit EL1.

In some examples, it is described as an example that all eight transistors in the pixel circuit are P-type transistors. The second reset control line RST2 may be connected to the scan line GL to be input with the first scan signal. In the anti-peeping display mode, the scan line GL can continuously provide a second scan signal of a high level, so that the first control transistor T8 is turned off and the second light-emitting unit EL2 is in a non-light-emitting state. In the sharing display mode, the scan line GL can continuously provide a second scan signal of a low-level, so that the first control transistor T8 is turned on, and the second light-emitting unit EL2 can emit light together with the first light-emitting unit EL1.

In some examples, taking the case where the first control transistor T8 is turned off in the anti-peeping display mode as an example, the operation process of the pixel circuit may include following stages.

The first stage is called the reset stage. The first reset control signal provided by the first reset control line RST1 is a low-level signal, so that the first reset transistor T1 is turned on. The first initial signal provided by the first initial signal line INIT1 can be provided to the first node N1 to initialize the first node N1 and clear the original data voltage in the storage capacitor Cst. The first scanning signal provided by the scan line GL is a high level signal, and the light-emitting control signal provided by the light-emitting control line EML is a high level signal, so that the data writing transistor T4, the threshold compensation transistor T2, the first light-emitting control transistor T5, the second light-emitting control transistor T6 and the second reset transistor T7 are turned off. In this stage, the first light-emitting unit EL1 does not emit light.

The second stage is called the data writing stage or the threshold compensation stage. The first scanning signal provided by the scan line GL is a low level signal, the first reset control signal provided by the first reset control line RST1 and the light-emitting control signal provided by the light-emitting control line EML are both high level signals, and the data line DL outputs a data signal. At this stage, since the first electrode plate of the storage capacitor Cst is at a low level, the driving transistor T3 is turned on. The first scanning signal is a low level signal, which turns on the threshold compensation transistor T2, the data writing transistor T4 and the second reset transistor T7. The threshold compensation transistor T2 and the data writing transistor T4 are turned on, so that the data voltage output by the data line DL is provided to the first node N1 through the second node N2, the turned-on driving transistor T3, the third node N3, and the turned-on threshold compensation transistor T2, and the difference between the data voltage output by the data line DL and the threshold voltage of the driving transistor T3 is charged into the storage capacitor Cst, and the voltage of the first electrode plate (i.e., the first node N1) of the storage capacitor Cst is Vdata−|Vth|. Vdata is the data voltage output by the data line DL, and Vth is the threshold voltage of the driving transistor T3. The second reset transistor T7 is turned on, so that the second initial signal provided by the second initial signal line INIT2 is provided to the fourth node N4, and the fourth node N4 is initialized to ensure that the first light-emitting unit EL1 does not emit light. The first reset control signal provided by the first reset control line RST1 is a high level signal, which turns off the first reset transistor T1. The light-emitting control signal provided by the light-emitting control signal line EML is a high level signal, which turns off the first light-emitting control transistor T5 and the second light-emitting control transistor T6.

The third stage is called the light-emitting stage. The light-emitting control signal provided by the light-emitting control signal line EML is a low level signal, and the first scanning signal provided by the scan line GL and the first reset control signal provided by the first reset control line RST1 are high level signals. The light control signal provided by the light control signal line EML is a low-level signal, which turns on the first light control transistor T5 and the second light control transistor T6. The first voltage signal output by the first power line VDD provides a driving voltage to the first anode of the first light-emitting unit EL1 through the turned-on first light control transistor T5, the driving transistor T3 and the second light control transistor T6, thereby driving the first light-emitting unit EL1 to emit light.

During the driving process of the pixel circuit, the driving current flowing through the driving transistor T3 is determined by the voltage difference between the gate and the first electrode of the driving transistor T3. Since the voltage of the first node N1 is Vdata−|Vth|, the driving current of the driving transistor T3 is: I=K×(Vgs−Vth)²=K×[(Vdd−Vdata+|Vth|)−Vth]²=K×[(Vdd−Vdata)]².

I is the driving current flowing through the driving transistor T3, that is, the driving current driving the light-emitting element EL. K is a constant. Vgs is the voltage difference between the gate and the first electrode of the driving transistor T3. Vth is the threshold voltage of the driving transistor T3. Vdata is the data voltage output by the data line DL. Vdd is the first voltage signal output by the first power line VDD.

It can be seen from the above formula that the driving current has nothing to do with the threshold voltage of the driving transistor T3. Therefore, the pixel circuit in embodiments of the present disclosure can better compensate for the threshold voltage of the driving transistor T3.

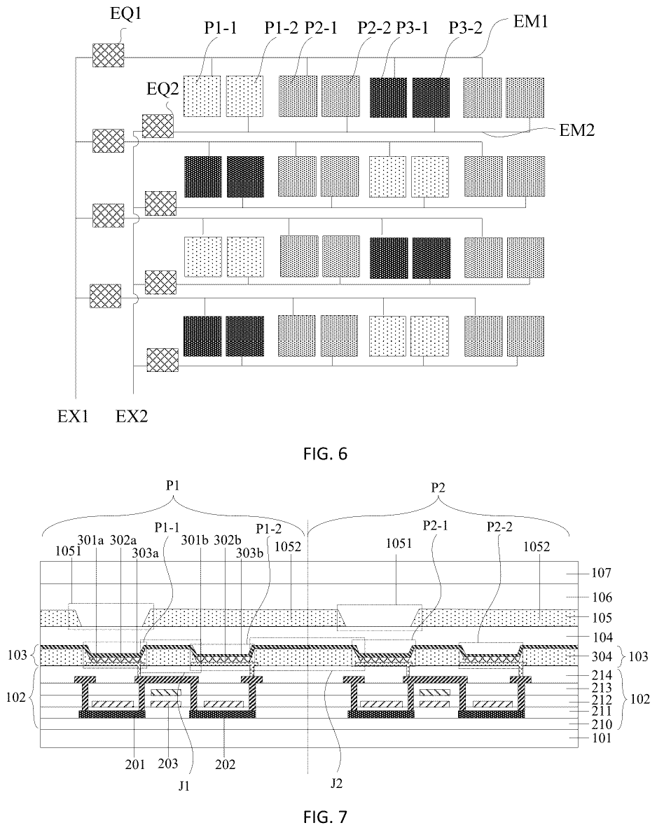

In some examples, as shown in FIG. 6, the display panel includes: a plurality of first light-emitting control lines EM1 and a plurality of second light-emitting control lines EM2 extending along a first direction X. The first light-emitting units of the same light-emitting element row are electrically connected to one same first light-emitting control line EM1, and the second light-emitting units of the same light-emitting element row are electrically connected to one same second light-emitting control line EM2. Specifically, for example, in the same row of light-emitting elements, the first light-emitting unit P1-1 of the first sub-pixel, the first light-emitting unit P2-1 of the second sub-pixel, and the first light-emitting unit P3-1 of the third sub-pixel are electrically connected to one same first light-emitting control line EM1. In the same row of light-emitting elements, the second light-emitting unit P1-2 of the first sub-pixel, the second light-emitting unit P2-2 of the second sub-pixel, and the second light-emitting unit P3-2 of the third sub-pixel are electrically connected to one same second light-emitting control line EM2.

In some examples, as shown in FIG. 6, in two adjacent rows, the first sub-pixel P1 and the third sub-pixel P3 are alternately located on both sides of the second sub-pixel P2. For example, in the odd row, the first sub-pixel P1 is located on the left side of the second sub-pixel P2, and the third sub-pixel P3 is located on the right side of the second sub-pixel P2. In the even row, the first sub-pixel P1 is located on the right side of the second sub-pixel P2, and the third sub-pixel P3 is located on the left side of the second sub-pixel P2. Such a design is conducive to dispersing the non-luminous units in the anti-peeping state, avoiding the appearance of obvious non-luminous dark bands, or avoiding the appearance of obvious dark bands of uneven size.

In some examples, as shown in FIG. 6, the display panel further includes: a first light-emitting control connection line EX1, a second light-emitting control connection line EX2, multiple first light-emitting control circuits EQ1, and multiple second light-emitting control circuits EQ2. Multiple first light-emitting control lines EM1 are electrically connected to the first light-emitting control connection line EX1 through the first light-emitting control circuits EQ1 in one-to-one correspondence. Multiple second light-emitting control lines EM2 are electrically connected to the second light-emitting control connection line EX2 through the second light-emitting control circuits EQ2 in one-to-one correspondence. The first light-emitting control circuit EQ1 is configured to provide a signal of the first light-emitting control connection line EX1 to the first light-emitting control line EM1 according to the light-emitting sub-pixel. The second light-emitting control circuit EQ2 is configured to provide a signal of the second light-emitting control connection line EX2 to the second light-emitting control line EM2 according to the light-emitting sub-pixel.

In some embodiments, as shown in FIG. 6, the first light-emitting control circuit EQ1 and the second light-emitting control circuit EQ2 may be switches for controlling the signals of the first light-emitting control connection line EX1 and the second light-emitting control connection line EX2 to be turned on or off, for example, using thin film transistors. For example: EQ1 is a P-type transistor, and EQ2 is an N-type transistor.

In some embodiments, as shown in FIG. 6, the first light-emitting control lines EM1 and the second light-emitting control lines EM2 may be arranged alternately. For example, the first light-emitting control line EM1 and the first light-emitting control line EM2 are respectively located at two sides of the same row of sub-pixels. The first light-emitting control connection line EX1 and the second light-emitting control connection line EX2 are respectively located at the same side of the display panel. Such a design is beneficial for the first light-emitting control line EM1 and the second light-emitting control line EM2 to independently control the light-emitting units controlled by them.

In some embodiments, as shown in FIG. 6, the first light-emitting control connection line EX1 and the second light-emitting control connection line EX2 are connected to the first gate driving circuit GOA1 and the second gate driving circuit GOA2, respectively. Of course, the first gate driving circuit GOA1 and the second gate driving circuit GOA2 may adopt the same circuit structure or different circuit structures.

In some embodiments, as shown in FIG. 6, the first light-emitting control circuit EQ1 and the second light-emitting control circuit EQ2 are respectively the first gate driving circuit GOA1 and the second gate driving circuit GOA2. The first light-emitting control connection line EX1 is the first initial signal line connected to the first gate driving circuit GOA1. The second light-emitting control connection line EX2 is the second initial signal line connected to a gate driving circuit GOA2. The turning on and turning off of the first gate driving circuit GOA1 and the second gate driving circuit GOA2 are respectively controlled by the timing of the first initial signal line and the timing of the second initial signal line, thereby controlling the conduction and non-conduction of the first light-emitting control line EM1 and the second light-emitting control line EM2. Of course, the first gate driving circuit GOA1 and the second gate driving circuit GOA2 may adopt the same circuit structure or different circuit structures.

The above-described pixel circuits are merely examples. Embodiments of the present disclosure do not limit the structure of the pixel circuit.

In this example, in the anti-peeping display mode, the first light-emitting unit EL1 of the light-emitting element of the sub-pixel is lit, and the second light-emitting unit EL2 is not lit, which can limit the area of the light-emitting region and light-emitting angle of the sub-pixel. In the sharing display mode, the first light-emitting unit EL1 and the second light-emitting unit EL2 of the light-emitting element of the sub-pixel can be lit at the same time, which can increase the area of the light-emitting region and light-emitting angle of the sub-pixel. Embodiments of the present disclosure can switch between anti-peeping effect and sharing effect.

FIG. 7 is an example of a partial cross-section view along the Q-Q′ direction in FIG. 3A, FIG. 3B, or FIG. 3C. FIG. 7 illustrates a partial cross-sectional structure of a first sub-pixel P1. In some examples, as shown in FIG. 7, in a direction perpendicular to the display panel, the display panel may include: a base substrate 101; and a display structure layer, an encapsulation structure layer 104, a first optical film layer 105, and a second optical film layer 106 sequentially arranged on the base substrate 101. The refractive index of the second optical film layer 106 is greater than the refractive index of the first optical film layer 105. The first optical film layer 105 has an isolation portion 1052 and a plurality of openings 1051. The orthographic projection of the opening 1051 on the base substrate 101 at least partially overlaps with the orthographic projection of the light-emitting region of the first light-emitting unit on the base substrate 101. Specifically, for example, in the first sub-pixel P1, the orthographic projection of the opening 1051 on the base substrate 101 at least partially overlaps with the orthographic projection of the light-emitting region of the first light-emitting unit P1-1 on the base substrate 101. For example, in the second sub-pixel P2, the orthographic projection of the opening 1051 on the base substrate 101 at least partially overlaps with the orthographic projection of the light-emitting region of the first light-emitting unit P2-1 on the base substrate 101. For example, in the third sub-pixel P3, the orthographic projection of the opening 1051 on the base substrate 101 at least partially overlaps with the orthographic projection of the light-emitting region of the first light-emitting unit P3-1 on the base substrate 101. In the embodiments of the present disclosure, by providing a first optical film layer 105 and a second optical film layer 106, when in the anti-peeping display mode, and when the light path is incident on the side wall of the opening 1051, total reflection is formed at the interface between the first optical film layer and the second optical film layer, so that the light path converges inward, the viewing angle is narrowed, and the light output efficiency is increased. This can improve the problem that when the light-emitting element is divided into a first light-emitting unit and a second light-emitting unit, the light-emitting region is reduced and the brightness is reduced. In addition, when the required brightness is constant, the current needs to be increased, resulting in a problem of reduced life of the display panel.

In some embodiments, the orthographic projection of the opening 1051 on the base substrate 101 partially overlaps with the orthographic projection of the light-emitting region of the first light-emitting unit on the base substrate 101. In other embodiments, the orthographic projection of the opening 1051 on the base substrate 101 covers the orthographic projection of the light-emitting region of the first light-emitting unit on the base substrate 101.

In some embodiments, the orthographic projection of the isolation portion 1052 on the base substrate 101 at least partially covers the orthographic projection of the light-emitting region of the second light-emitting unit on the base substrate. Specifically, the orthographic projection of the isolation portion 1052 on the base substrate 101 may be an orthographic projection that partially covers the light-emitting region of the second light-emitting unit on the base substrate. Specifically, the orthographic projection of the isolation portion 1052 on the base substrate 101 may be an orthographic projection that completely covers the light-emitting region of the second light-emitting unit on the base substrate. Specifically, for example, in the first sub-pixel P1, the orthographic projection of the isolation portion 1052 on the base substrate 101 covers the orthographic projection of the light-emitting region of the second light-emitting unit P1-2 on the base substrate 101. For example, in the second sub-pixel P2, the orthographic projection of the isolation portion 1052 on the base substrate 101 covers the orthographic projection of the light-emitting region of the second light-emitting unit P2-2 on the base substrate 101. For example, in the third sub-pixel P3, the orthographic projection of the isolation portion 1052 on the base substrate 101 covers the orthographic projection of the light-emitting region of the second light-emitting unit P3-2 on the base substrate 101.

In some embodiments, the orthographic projection of the isolation portion 1052 on the base substrate 101 at least partially covers the orthographic projection of the first gap J1 between the light-emitting region of the first light-emitting unit and the light-emitting region of the second light-emitting unit on the base substrate 101, and at least partially covers the orthographic projection of the second gap J2 between different light-emitting elements on the base substrate. Specifically, the orthographic projection of the isolation portion 1052 on the base substrate 101 may be an orthographic projection that partially covers the orthographic projection of the first gap J1 between the light-emitting region of the first light-emitting unit and the light-emitting region of the second light-emitting unit on the base substrate 101, and an orthographic projection that partially covers the orthographic projection of the second gap J2 between different light-emitting elements on the base substrate. Specifically, the orthographic projection of the isolation portion 1052 on the base substrate 101 may also be an orthographic projection that completely covers the orthographic projection of the first gap J1 between the light-emitting region of the first light-emitting unit and the light-emitting region of the second light-emitting unit on the base substrate 101, and an orthographic projection that completely covers the second gap J2 between different light-emitting elements on the base substrate.

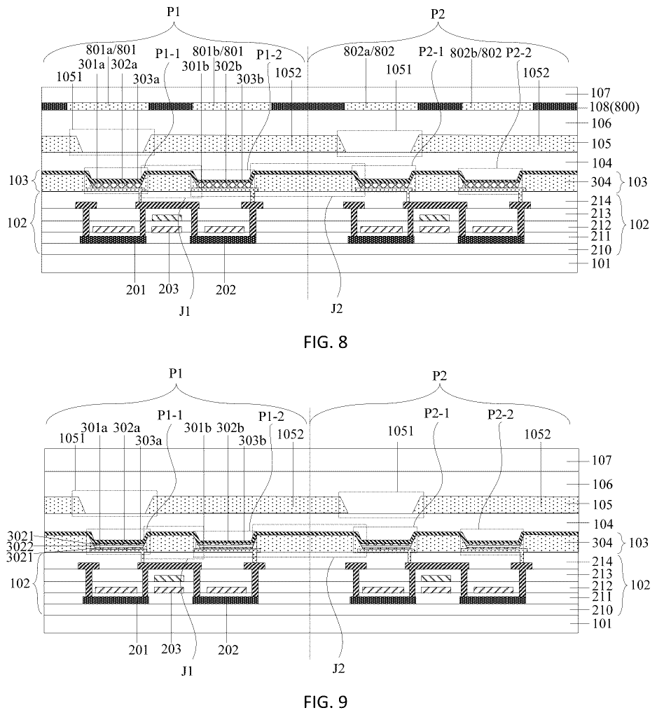

In some embodiments, as shown in FIG. 8, in the display panel, an orthographic projection of the isolation portion 1052 on the base substrate 101 completely covers the orthographic projection of the black matrix between the light-emitting region of the first light-emitting unit and the light-emitting region of the second light-emitting unit on the base substrate 101, and completely covers the orthographic projection of the black matrix between different light-emitting elements on the base substrate. For example, the orthographic projection of the isolation portion 1052 on the base substrate 101 completely covers the orthographic projection of the black matrix between the light-emitting region of the first light-emitting unit P1-1 of the first sub-pixel P1 and the light-emitting region of the second light-emitting unit P1-2 of the first sub-pixel P1 on the base substrate 101, and completely cover the orthographic projection of the black matrix between the light-emitting region of the second light-emitting unit P1-2 of the first sub-pixel P1 and the light-emitting region of the first light-emitting unit P2-1 of the second sub-pixel P2 on the base substrate 101.

In some embodiments, in the display panel, the isolation portion 1052 may be an integrally connected structure disposed around the openings 1051. In some embodiments, the isolation portion 1052 may also be a mutually separated structure.

The display structure layer may include: a circuit structure layer 102 and a light-emitting structure layer 103 which are sequentially arranged on a base substrate 101. Specifically, the light-emitting structure layer 103 may include a pixel definition layer 304. The pixel definition layer 304 has a plurality of pixel openings. The light-emitting region may specifically be a region exposed by the pixel opening. Specifically, the plurality of pixel openings may include a first pixel opening and a second pixel opening. The first pixel opening may expose at least a portion of the first anode 301a of the first light-emitting unit, and the second pixel opening may expose at least a portion of the second anode 301b of the second light-emitting unit.

In some possible implementations, the display panel may include other film layers, such as spacers and columns, etc., which is not limited in the present disclosure.

The manufacturing process of the display panel is exemplarily described below with reference to FIG. 7. The “patterning process” in the present disclosure includes processes such as coating photoresist, mask exposure, development, etching, and photoresist stripping for metal materials, inorganic materials, or transparent conductive materials; and includes processes such as coating organic materials, mask exposure, and development for organic materials. Deposition can be carried out by any one or more of sputtering, evaporation, and chemical vapor deposition, coating can be carried out by any one or more of spraying, spin coating, and inkjet printing, and etching can be carried out by any one or more of dry etching and wet etching, which is not limited in the present disclosure. “Thin film” refers to a layer of a certain material produced on a base substrate by deposition, coating or other processes. If the “film” does not require a patterning process during the entire manufacturing process, the “film” can also be called a “layer”. If the “film” requires a patterning process during the entire manufacturing process, it is called a “film” before the patterning process and is called a “layer” after the patterning process. The “layer” after the patterning process contains at least one “pattern”. In exemplary embodiments of the present disclosure, “the orthographic projection of B is within the range of the orthographic projection of A” or “the orthographic projection of A contains the orthographic projection of B” means that the boundary of the orthographic projection of B falls within the boundary range of the orthographic projection of A, or the boundary of the orthographic projection of A coincides with the boundary of the orthographic projection of B.

In some examples, the manufacturing process of the display panel may include the following operations.

(1) Provide a base substrate 101. In some examples, the base substrate 101 may be a flexible base substrate, or may be a rigid base substrate. For example, the rigid base substrate may include a glass base substrate. The flexible base substrate may include a stacked first flexible material layer, a first inorganic material layer, a semiconductor layer, a second flexible material layer and a second inorganic material layer. The materials of the first flexible material layer and the second flexible material layer may be polyimide (PI), polyethylene terephthalate (PET) or a surface-treated polymer soft film, etc. The materials of the first inorganic material layer and the second inorganic material layer may be silicon nitride (SiNx) or silicon oxide (SiOx), etc., which are used to improve the water and oxygen resistance of the base substrate. The material of the semiconductor layer may be amorphous silicon (a-Si).

However, the embodiments are not limited to these.

(2) Forming a circuit structure layer 102. In some examples, the circuit structure layer 102 may include: transistors and storage capacitors of multiple pixel circuits. FIG. 7 illustrates a structure of two transistors (e.g., a first transistor 201 and a second transistor 202) and a storage capacitor 203 in a pixel circuit as an example. For example, the first transistor 201 may be the driving transistor T3, the second reset transistor T7 or the second light-emitting control transistor T6 in the aforementioned pixel circuit. The second transistor 202 may be the first control transistor T8 in the aforementioned pixel circuit, and the storage capacitor 203 may be the storage capacitor Cst in the aforementioned pixel circuit.

In some examples, as shown in FIG. 7, the circuit structure layer 102 may include: a buffer layer 210, a semiconductor layer, a first insulating layer 211, a first gate metal layer, a second insulating layer 212, a second gate metal layer, a third insulating layer 213, a first source and drain metal layer, and a fourth insulating layer 214, which are sequentially arranged on the base substrate 101.

In some examples, as shown in FIG. 7, a buffer film and a semiconductor film are sequentially deposited on the base substrate 101 forming the aforementioned structure. The semiconductor film is patterned in a patterning process to form a buffer layer 210 and a semiconductor layer disposed on the buffer layer 210. For example, the semiconductor layer may include at least: an active layer of the first transistor 201 and an active layer of the second transistor 202.

Subsequently, a first insulating film and a first conductive film are sequentially deposited on the base substrate 101 forming the aforementioned structure. The first conductive film is patterned in a patterning process to form a first insulating layer 211 and a first gate metal layer disposed on the first insulating layer 211. For example, the first gate metal layer may include at least: a gate of the first transistor 201, a gate of the second transistor 202, and a first electrode plate of the storage capacitor 203.

In some examples, after forming the first gate metal layer, the semiconductor layer can be conductorized using the first gate metal layer as a shield. The semiconductor layer in the region shielded by the first gate metal layer can form a channel region of the transistor, and the semiconductor layer in the region not shielded by the first gate metal layer can be conductorized. That is, the first region and the second region of the active layer of multiple transistors of the pixel circuit are both conductorized.

Subsequently, a second insulating film and a second conductive film are sequentially deposited on the base substrate forming the aforementioned structure, and the second conductive film is patterned in a patterning process to form a second insulating layer 212 and a second gate metal layer disposed on the second insulating layer 212. For example, the second gate metal layer may at least include: a second electrode plate of the storage capacitor 203. The orthographic projection of the second electrode plate of the storage capacitor 203 on the base substrate and the orthographic projection of the first electrode plate of the storage capacitor 203 on the base substrate may at least partially overlap.

Subsequently, a third insulating film is deposited on the base substrate forming the aforementioned structure, and the third insulating film is patterned in a patterning process to form a third insulating layer 213. The third insulating layer 213 may be provided with a plurality of via holes. For example, the plurality of via holes of the third insulating layer 213 may expose surfaces of the semiconductor layer, the first gate metal layer, and the second gate metal layer, respectively.

Subsequently, a third conductive film is deposited on the base substrate forming the aforementioned structure, and the third conductive film is patterned in a patterning process to form a first source-drain metal layer on the third insulating layer 213. For example, the first source-drain metal layer may include at least: a first electrode and a second electrode of the first transistor 201, and a first electrode and a second electrode of the second transistor 202. For example, the second electrode of the first transistor 201 and the first electrode of the second transistor 202 may be an integral structure. Subsequently, a fourth insulating film is coated on the base substrate forming the aforementioned structure, and a fourth insulating layer 214 is formed by a patterning process.

In some examples, for example, in combination with FIG. 5 and FIG. 7, the first transistor 201 in FIG. 7 is the sixth transistor T6 in FIG. 5, and the second transistor 202 in FIG. 7 is the eighth transistor T8 in FIG. 5. The first electrode of the first transistor 201 is connected to the third node N3, and the second electrode of the first transistor 201 is connected to the anode of EL1. The first electrode of the second transistor 202 is connected to the second electrode of the first transistor 201, and the second electrode of the second transistor 202 is connected to the anode of EL2.

In some examples, the buffer layer 210, the first insulating layer 211, the second insulating layer 212, and the third insulating layer 213 may be inorganic insulating layers, and the fourth insulating layer 214 may be an organic insulating layer. For example, the buffer layer 210, the first insulating layer 211, the second insulating layer 212 and the third insulating layer 213 may be made of any one or more of silicon oxide (SiOx), silicon nitride (SiNx) and silicon oxynitride (SiON), and may be a single layer, a multilayer or a composite layer. The first insulating layer 211 and the second insulating layer 212 may be referred to as a gate insulating (GI) layer, the third insulating layer 213 may be referred to as an interlayer insulating (ILD) layer, and the fourth insulating layer 214 may be referred to as a planar layer. The first gate metal layer, the second gate metal layer and the first source and drain metal layer can be made of metal materials, such as any one or more of silver (Ag), copper (Cu), aluminum (Al), titanium (Ti) and molybdenum (Mo), or alloy materials of the above metals, such as aluminum-neodymium alloy (AlNd) or molybdenum-niobium alloy (MoNb), and can be a single-layer structure, or a multi-layer composite structure, such as Ti/Al/Ti, etc. The semiconductor layer can be made of amorphous indium gallium zinc oxide material (a-IGZO), zinc oxynitride (ZnON), indium zinc tin oxide (IZTO), amorphous silicon (a-Si), polycrystalline silicon (p-Si), sexithiophene or polythiophene and the like, that is, the present disclosure is applicable to transistors manufactured based on oxide technology, silicon technology or organic technology.

(3) Forming the light-emitting structure layer 103. In some examples, the light-emitting structure layer 103 may include a plurality of light-emitting elements.

In some examples, an anode film is deposited on the base substrate forming the aforementioned structure, and the anode film is patterned in a patterning process to form an anode layer. For example, the anode layer may include: a first anode 301a of a first light-emitting unit and a second anode 301b of a second light-emitting unit. The first anode 301a and the second anode 301b may be independent of each other. The planes where the first anode 301a and the second anode 301b are located may be flush. The first anode 301a may be electrically connected to the second electrode of the first transistor 201 of the pixel circuit through a via hole formed in the fourth insulating layer 214, and the second anode 301b may be electrically connected to the second electrode of the second transistor 202 of the pixel circuit through a via hole formed in the fourth insulating layer 214.

Subsequently, a pixel definition film is coated on the base substrate forming the aforementioned structure, and a pixel definition layer 304 is formed through masking, exposure and development processes. The pixel definition layer 304 is formed with a plurality of pixel openings exposing the anode layer. For example, the plurality of pixel openings may include a first pixel opening and a second pixel opening. The first pixel opening may expose at least a portion of the first anode 301a, and the second pixel opening may expose at least a portion of the second anode 301b.

Subsequently, an organic light-emitting layer is formed in the pixel opening formed above. For example, a first organic light-emitting layer 302a is formed in the first pixel opening and connected to the first anode 301a. A second organic light-emitting layer 302b is formed in the second pixel opening and connected to the second anode 301b.

Subsequently, a cathode film is deposited and patterned in a patterning process to form a cathode layer. For example, the cathode layer may include a first cathode 303a of a first light-emitting unit and a second cathode 303b of a second light-emitting unit. The first cathode 303a is connected to the first organic light-emitting layer 302a, and the second cathode 303b is connected to the second organic light-emitting layer 302b. The first cathode 303a and the second cathode 303b may be an integral structure. The first organic light-emitting layer 302a can emit light of corresponding color under the action of voltage applied by the first anode 301a and the first cathode 303a. The second organic light-emitting layer 302b can emit light of corresponding color under the action of voltage applied by the second anode 301b and the second cathode 303b. For example, the first light-emitting unit and the second light-emitting unit of the first sub-pixel P1 may both be configured to emit red light.

In some examples, the pixel definition layer 304 may be made of organic materials such as polyimide, acrylic, polyethylene terephthalate, or acrylate. For example, the pixel definition layer 304 may be black. By providing a black pixel definition layer 304, the reflected light and refracted light in the film layer can be absorbed, thereby improving the light-emitting effect of the light-emitting element. However, the embodiments are not limited to these.

In some examples, the organic light-emitting layer may include a stacked hole injection layer (HIL), a hole transport layer (HTL), an electron blocking layer (EBL), an emitting layer (EML), a hole blocking layer (HBL), an electron transport layer (ETL), and an electron injection layer (EIL). In some examples, the first organic light-emitting layer 302a of the first light-emitting unit and the second organic light-emitting layer 302a of the second light-emitting unit may be isolated from each other. However, the embodiments are not limited to this. For example, in some examples, the hole injection layers of all sub-pixels may be a common layer connected together. The electron injection layers of all sub-pixels may be a common layer connected together. The hole transport layers of all sub-pixels may be a common layer connected together. The electron transport layers of all sub-pixels may be a common layer connected together. The hole blocking layers of all sub-pixels may be a common layer connected together. The light-emitting layers of adjacent sub-pixels may have a small amount of overlap, or may be isolated, and the electron blocking layers of adjacent sub-pixels may have a small amount of overlap, or may be isolated.

In some examples, the light-emitting region of the light-emitting unit may be an overlapping region of the anode exposed by the pixel opening of the pixel definition layer with the organic light-emitting layer and the cathode. For example, the light-emitting region of the first light-emitting unit may be an overlapping region of the first anode, the first organic light-emitting layer, and the first cathode within the first pixel opening of the pixel definition layer. The light-emitting region of the second light-emitting unit may be an overlapping region of the second anode, the second organic light-emitting layer, and the second cathode within the second pixel opening of the pixel definition layer.

(4) Forming a packaging structure layer 104. In some examples, the encapsulation structure layer 104 is located on a side of the cathode layer away from the base substrate 101. The encapsulation structure layer 104 may include a stacked first encapsulation layer, a second encapsulation layer and a third encapsulation layer. The first encapsulation layer and the third encapsulation layer may be made of inorganic materials. The second encapsulation layer may be made of organic materials. The second encapsulation layer may be arranged between the first encapsulation layer and the third encapsulation layer, which can ensure that external water and vapor cannot enter the light-emitting structure layer 103. In some other examples, the encapsulation structure layer 104 may adopt a stacked structure of inorganic material/organic material/inorganic material/organic material/inorganic material.

(5) Forming a first optical film layer 105. As shown in FIG. 7, specifically, a first optical film may be formed first, and then the first optical film may be patterned to form a first optical film layer 105 having a plurality of openings 1051.

(6) A second optical film layer 106. In some examples, a second optical film layer 106 is coated on the base substrate forming the aforementioned structure. The second optical film layer 106 may be formed of a high-refractive index protective layer OC (Over Coat) or a high-refractive index ink. In some examples, the second optical film layer 106 may be made of materials such as acrylates.

(7) The cover plate 107 is formed. Specifically, the cover plate 107 may be a glass cover plate.

The structure of the display panel and the manufacturing process thereof of the exemplary embodiments of the present disclosure are merely exemplary descriptions. In some exemplary embodiments, the corresponding structure may be changed and the patterning process may be increased or decreased according to actual needs. For example, the display structure layer may also include a second source-drain metal layer located on the side of the first source-drain metal layer away from the base substrate. The second source-drain metal layer may include an anode connecting electrode. The first anode of the first light-emitting unit and the second anode of the second light-emitting unit may be electrically connected to the pixel circuit through the anode connecting electrode, respectively. However, the present disclosure is not limited thereto.

FIG. 8 is another example of a partial cross-section view along the Q-Q′ direction in FIG. 3A, FIG. 3B, or FIG. 3C. In some examples, as shown in FIG. 8, in a direction perpendicular to the display panel, the display panel may include: a base substrate 101, and a display structure layer, an encapsulation structure layer 104, a first optical film layer 105, a second optical film layer 106 and a color filter layer 108 sequentially arranged on the base substrate 101. The display structure layer may include: a circuit structure layer 102 and a light-emitting structure layer 103 which are sequentially arranged on a base substrate 101. The structures of the display structure layer, the encapsulation structure layer 104, the first optical film layer 105, and the second optical film layer 106 may refer to the description of the aforementioned embodiments, and thus will not be described in detail herein.

In some examples, as shown in FIG. 8, the color filter layer 108 may be located on a side of the first protection layer 106 away from the base substrate 101. The color filter layer 108 may include: a plurality of periodically arranged filter units and a black matrix 800 disposed between adjacent filter units. The plurality of filter units may correspond one-to-one to the light-emitting elements of the plurality of sub-pixels. For example, the plurality of filter units may include a first filter unit 801, a second filter unit 802, and a third filter unit. The first filter unit 801 may correspond to the light-emitting element of the first sub-pixel P1, the second filter unit may correspond to the light-emitting element of the second sub-pixel P2, and the third filter unit may correspond to the light-emitting element of the third sub-pixel P3. For example, the first filter unit 801 may be a red filter unit, the second filter unit 802 may be a green filter unit, and the third filter unit may be a blue filter unit.

In embodiments of the present disclosure, the filter unit can allow light of a single color to pass through and absorb light of other colors. For example, the blue filter unit allows blue light to pass through and absorbs other colors of light, the red filter unit allows red light to pass through and absorbs other colors of light, and the green filter unit allows green light to pass through and absorbs other colors of light.

In some examples, the at least one filter unit may include: a first sub-filter unit and a second sub-filter unit. The orthographic projection of the filter unit on the base substrate can cover the orthographic projection of the light-emitting region of the corresponding light-emitting element on the base substrate. For example, as shown in FIG. 8, the first filtering unit 801 may include a first sub-filtering unit 801a and a second sub-filtering unit 801b. The orthographic projection of the first sub-filter unit 801a on the base substrate 101 can cover the orthographic projection of the light-emitting region of the first light-emitting unit of the first sub-pixel on the base substrate 101. The orthographic projection of the second sub-filter unit 801b on the base substrate 101 can cover the orthographic projection of the light-emitting region of the second light-emitting unit of the first sub-pixel on the base substrate 101. The second filtering unit 802 may include a first sub-filtering unit 802a and a second sub-filtering unit 802b. The orthographic projection of the first sub-filter unit 802a on the base substrate 101 can cover the orthographic projection of the light-emitting region of the first light-emitting unit of the second sub-pixel on the base substrate 101. The orthographic projection of the second sub-filter unit 802b on the base substrate 101 can cover the orthographic projection of the light-emitting region of the second light-emitting unit of the second sub-pixel on the base substrate 101. However, the embodiments are not limited to these. In some other examples, the orthographic projection of a filter unit on the base substrate may cover the orthographic projection of the light-emitting regions of the first light-emitting unit and the second light-emitting unit of the corresponding light-emitting element on the base substrate.

In some examples, after the second optical film layer 106 is prepared, the color filter layer 108 can be prepared in the following manner. Black pigment is coated on the first protective layer 106 or a black chromium (Cr) film is deposited. The black pigment or the black chromium film is patterned in a patterning process to form a black matrix 800. Then, a plurality of first filter units 801, a plurality of second filter units 802, and a plurality of third filter units are formed in sequence. Taking the first filter unit 801 as a red filter unit as an example, a red resin is first coated on the first protection layer 106 on which the black matrix 800 has been formed. After being baked and cured, the red resin is exposed through a mask and developed to form a red filter unit. The formation process of the green filter unit and the blue filter unit is similar, so it will not be described again here.

In this example, by setting a color filter layer, the circular polarizer can be replaced, which can reduce the reflection of ambient light, improve the contrast of the display panel, effectively resist ambient light, reduce display interference, and avoid reflection of external ambient light. Moreover, by providing a color filter layer instead of a circular polarizer, the thickness of the display panel can be reduced and the flexibility of the device can be improved.

Specifically, when a color filter layer is provided to replace a circular polarizer, in embodiments of the present disclosure, the orthographic projection of the light-emitting region of the first light-emitting unit on the base substrate can be a circle, and the orthographic projection of the light-emitting region of the second light-emitting unit on the base substrate can be a circle, so as to enhance the optical effect and color separation effect of the display panel structure.

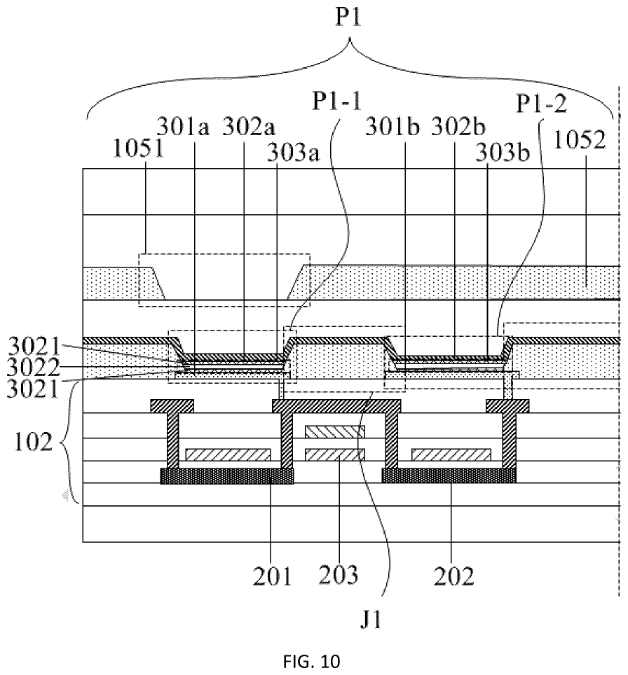

In some embodiments, referring to FIGS. 9 and 10, FIG. 9 is another example of a partial cross-sectional view along the Q-Q′ direction in FIG. 3A or FIG. 3B or FIG. 3C. FIG. 10 is a partial enlarged schematic diagram of FIG. 9. In some examples, as shown in FIG. 9 and FIG. 10, the display structure layer includes an anode layer and a plurality of light-emitting layers 3021 located on the side of the anode layer away from the base substrate. The light-emitting layers 3021 of the same light-emitting element have the same light-emitting color, and the light-emitting layers 3021 of different light-emitting elements have different light-emitting colors. In embodiments of the present disclosure, by setting multiple light-emitting layers 3021 to form a stacked series device, the problems of reduced lifespan and brightness caused by the dual-pixel structure and the high-refractive index second optical film layer 106 design can be improved, so that the display panel can achieve anti-peeping while having a lifespan and brightness not lower than conventional product specifications. Specifically, the display structure layer may include two light-emitting layers 3021 located on the side of the anode layer away from the base substrate.

In some embodiments, referring to FIG. 9 and FIG. 10, the display structure layer further includes: a charge transfer layer 3022 (Charge Generation Layer, CGL) located between adjacent light-emitting layers 3021. In embodiments of the present disclosure, the multiple light-emitting layers 3021 are connected in series through the CGL layer, and the current efficiency can be greatly improved, which effectively solves the problems of lifespan and insufficient brightness of the anti-peeping display panel.

In some embodiments, referring to FIG. 9 and FIG. 10, the second light-emitting unit of at least one sub-pixel includes one more light-emitting layer 3021 than the first light-emitting unit of the at least one sub-pixel. For example, the second light-emitting unit P1-2 of the first sub-pixel includes two light-emitting layers 3021, and the first light-emitting unit P1-1 of the first sub-pixel includes one light-emitting layer 3021. Such a design is conducive to ensuring that the luminous lifespan and brightness attenuation of the second light-emitting unit and the first light-emitting unit are as consistent as possible. Since the second light-emitting unit P1-2 (e.g., in the sharing state) has a higher turn-on frequency, the luminous lifespan and brightness attenuation are higher than those of the first light-emitting unit P1-1 (e.g., in the anti-peeping state).

The structures of the display structure layer, the encapsulation structure layer 104, the first optical film layer 105, and the second optical film layer 106 may refer to the description of the aforementioned embodiments, and thus will not be described in detail herein.

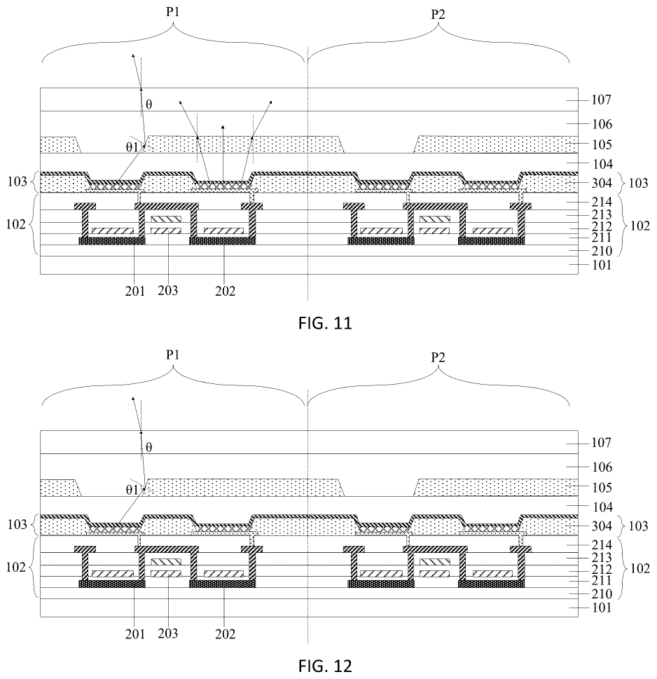

FIG. 11 is a schematic diagram of light emission of the cross-sectional structure in the anti-peeping display mode along the Q-Q′ direction in FIG. 3A, FIG. 3B or FIG. 3C. FIG. 12 is a schematic diagram of light emission of the cross-sectional structure in the sharing display mode along the Q-Q′ direction in FIG. 3A, FIG. 3B or FIG. 3C. FIG. 11 illustrates the emitted light of the first light-emitting unit P1-1 of the first sub-pixel P1 and the first light-emitting unit P2-1 of the second sub-pixel P2 as an example. FIG. 12 illustrates the emitted light of the second light-emitting unit P1-2 of the first sub-pixel P1 and the second light-emitting unit P2-2 of the second sub-pixel P2 as an example. The emitted light of the first sub-pixel P1 and the second sub-pixel P2 can be represented by solid lines with arrows.

In some examples, as shown in FIG. 11, the refractive index of the first optical film layer 105 is n1, and the refractive index of the second optical film layer 106 is n2. n2>n1. When in the anti-peeping display mode, the light path forms total reflection at the interface between the high-refractive and low-refractive materials (the slope angle of the first optical film layer 105 can be designed according to the difference in the refractive index of the interface to meet the total reflection condition), so that the light path converges inward, the viewing angle is narrowed, and the light output efficiency of the display panel is improved.

In some examples, as shown in FIG. 12, when in a sharing display mode, the first light-emitting unit and the second light-emitting unit both emit light. After the light path enters the second optical film layer 106 at the position where the first optical film layer 105 is present, it is refracted in all directions to achieve a sharing viewing mode.

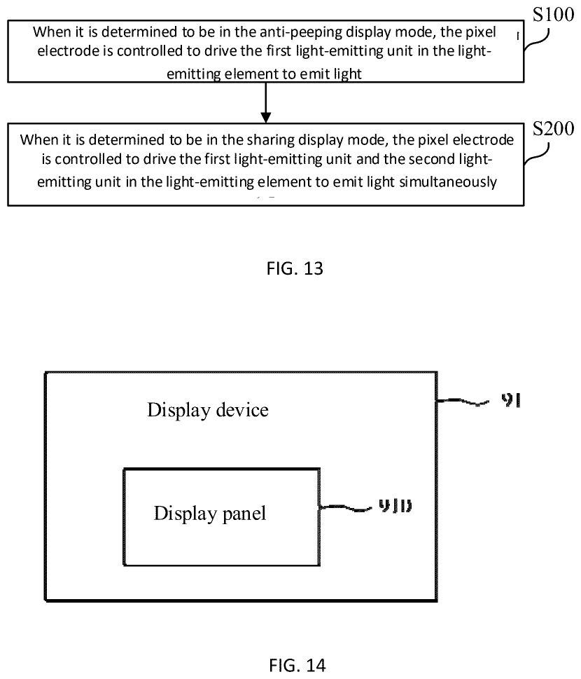

Embodiments of the present disclosure further provide a method for driving a display panel, as shown in FIG. 13, including the following steps.

Step S100: When it is determined to be in the anti-peeping display mode, the pixel electrode is controlled to drive the first light-emitting unit in the light-emitting element to emit light.

Step S200: When it is determined to be in the sharing display mode, the pixel electrode is controlled to drive the first light-emitting unit and the second light-emitting unit in the light-emitting element to emit light simultaneously.

The method for manufacturing the display panel of the embodiments of the present disclosure can refer to the description of the aforementioned embodiments, so it will not be described in detail here.

FIG. 14 is a schematic diagram of a display device according to at least one embodiment of the present disclosure. In some examples, as shown in FIG. 14, the embodiments of the present disclosure provide a display device 91 including the display panel 910 of the aforementioned embodiments. In some examples, the display panel 910 may be an OLED display substrate, a QLED display substrate, a Micro-LED display substrate, or a Mini-LED display substrate. The display device 91 may be any product or component with a display function, such as a mobile phone, a tablet computer, a television, a monitor, a laptop computer, a digital photo frame or a navigator. However, the embodiments are not limited to these.

Although preferred embodiments of the present disclosure have been described, additional changes and modifications may be made to these embodiments once those skilled in the art are aware of the basic inventive concepts. Therefore, it is intended that the appended claims be interpreted as including the preferred embodiment as well as all changes and modifications that fall within the scope of the present disclosure.

Obviously, those skilled in the art can make various changes and modifications to the present disclosure without departing from the spirit and scope of the present disclosure. Thus, if these modifications and variations of the present disclosure fall within the scope of the claims of the present disclosure and their equivalent technologies, the present disclosure is also intended to include these modifications and variations.

1.-21. (canceled)

22. A display panel, comprising:
a base substrate;
a display structure layer on a side of the base substrate; wherein the display structure layer comprises a plurality of sub-pixels; at least one of the plurality of sub-pixels comprises: a pixel circuit and a light-emitting element electrically connected to the pixel circuit; the light-emitting element comprises: a first light-emitting unit and a second light-emitting unit; a light-emitting region of the first light-emitting unit is isolated from a light-emitting region of the second light-emitting unit;
an optical component on a light-emitting side of the display structure layer; wherein the optical component comprises: a first optical film layer, and a second optical film layer on a side of the first optical film layer away from the base substrate; an refractive index of the second optical film layer is greater than an refractive index of the first optical film layer; the first optical film layer is provided with an isolation portion and a plurality of openings; an orthographic projection of the opening on the base substrate at least partially overlaps with an orthographic projection of the light-emitting region of the first light-emitting unit on the base substrate.

23. The display panel according to claim 22, wherein an orthographic projection of the isolation portion on the base substrate at least partially covers an orthographic projection of the light-emitting region of the second light-emitting unit on the base substrate.

24. The display panel according to claim 22, wherein an orthographic projection of the isolation portion on the base substrate at least partially covers an orthographic projection of a first gap between the light-emitting region of the first light-emitting unit and the light-emitting region of the second light-emitting unit on the base substrate, and at least partially covers an orthographic projection of a second gap between different light-emitting elements on the base substrate.

25. The display panel according to claim 22, wherein the plurality of sub-pixels comprise: a first sub-pixel emitting a first color light, a second sub-pixel emitting a second color light, and a third sub-pixel emitting a third color light;
the light-emitting element of the third sub-pixel and the light-emitting element of the first sub-pixel are sequentially distributed along a first direction; and the light-emitting element of the first sub-pixel and the light-emitting element of the second sub-pixel are sequentially distributed in a second direction;
the first light-emitting unit and the second light-emitting unit are distributed in sequence along the second direction.

26. The display panel according to claim 25, wherein an area of an orthographic projection the light-emitting region of the first light-emitting unit of at least one light-emitting element on the base substrate is smaller than an area of an orthographic projection of the light-emitting region of the second light-emitting unit of the at least one light-emitting element on the base substrate.

27. The display panel according to claim 26, wherein a maximum length of the light-emitting region of the first light-emitting unit of at least one light-emitting element in the second direction is smaller than a maximum length of the light-emitting region of the second light-emitting unit of the at least one light-emitting element in the second direction.

28. The display panel according to claim 26, wherein a maximum length of the first light-emitting unit of at least one light-emitting element in the first direction is smaller than a maximum length of the second light-emitting unit of the at least one light-emitting element in the first direction.

29. The display panel according to claim 28, wherein a shape of the light-emitting region of the first light-emitting unit of at least one light-emitting element is substantially similar to a shape of the light-emitting region of the second light-emitting unit of the at least one light-emitting element.

30. The display panel according to claim 28, wherein the light-emitting region of the second light-emitting unit of at least one light-emitting element comprises:
a second light-emitting main part, and a second light-emitting branch part extending from the second light-emitting main part along the second direction;
wherein the light-emitting region of the first light-emitting unit and the second light-emitting branch part are located on a same side of the second light-emitting main part.

31. The display panel according to claim 30, wherein a maximum length of the light-emitting region of the first light-emitting unit of at least one light-emitting element in the second direction is smaller than a maximum length of the second light-emitting branch part of the at least one light-emitting element in the second direction.

32. The display panel according to claim 22, wherein the display panel further comprises:
a color filter layer on a side of the optical component away from the base substrate;
the color filter layer comprising:
a plurality of filter units periodically arranged, and
a black matrix between adjacent filter units,
wherein the plurality of filter units correspond one-to-one to the light-emitting elements of the plurality of sub-pixels.

33. The display panel according to claim 22, wherein the display structure layer comprises:
an anode layer, and
a plurality of light-emitting layers on a side of the anode layer away from the base substrate;
wherein the light-emitting layers of the same light-emitting element have the same light-emitting color, and the light-emitting layers of different light-emitting elements have different light-emitting colors.

34. The display panel according to claim 33, wherein the display structure layer further comprises:
a charge transfer layer between adjacent light-emitting layers.

35. The display panel according to claim 22, wherein the display panel comprises:
a plurality of first light-emitting control lines and a plurality of second light-emitting control lines extending along the first direction;
wherein the first light-emitting units in the same light-emitting element row are electrically connected to the same first light-emitting control line, and the second light-emitting units in the same light-emitting element row are electrically connected to the same second light-emitting control line.

36. The display panel according to claim 35, wherein the display panel further comprises:
a first light-emitting control connection line,
a second light-emitting control connection line,
a plurality of first light-emitting control circuits, and
a plurality of second light-emitting control circuits;
wherein the plurality of first light-emitting control lines are electrically connected to the first light-emitting control connection line through the first light-emitting control circuits in one-to-one correspondence; and the plurality of second light-emitting control lines are electrically connected to the second light-emitting control connection line through the second light-emitting control circuits in one-to-one correspondence;
the first light-emitting control circuit is configured to provide a signal of the first light-emitting control connection line to the first light-emitting control line; the second light-emitting control circuit is configured to provide a signal of the second light-emitting control connection line to the second light-emitting control line.

37. The display panel according to claim 35, wherein the pixel circuit comprises at least: a data writing sub-circuit, a storage sub-circuit, a driving sub-circuit and a control sub-circuit;
wherein the data writing sub-circuit is electrically connected to a data line, a scan line and the driving sub-circuit, and is configured to provide the driving sub-circuit with a data signal transmitted by the data line under control of the scan line;
the driving sub-circuit is electrically connected to the data writing sub-circuit, the storage sub-circuit, the control sub-circuit and the first light-emitting unit of the light-emitting element, and is configured to drive the first light-emitting unit to emit light under control of the data signal;
the control sub-circuit is electrically connected to the second light-emitting control line, the driving sub-circuit, the first light-emitting unit and the second light-emitting unit of the light-emitting element, and is configured to control the second light-emitting unit to emit light together with the first light-emitting unit under control of the second light-emitting control line.

38. The display panel according to claim 37, wherein the control sub-circuit comprises:
a first control transistor;
wherein a gate of the first control transistor is electrically connected to the second light-emitting control line, a first electrode of the first control transistor is electrically connected to the driving sub-circuit, and a second electrode of the first control transistor is electrically connected to the second light-emitting unit.

39. The display panel according to claim 38, wherein the control sub-circuit further comprises:
a second control transistor;
wherein a gate of the second control transistor is electrically connected to a second reset control line, a first electrode of the second control transistor is electrically connected to a second initial signal line, and a second electrode of the second control transistor is electrically connected to the second light-emitting unit.

40. A display device, comprising the display panel according to claim 22.

41. A method for driving a display panel according to claim 22, comprising:
in response to determining to display in an anti-peeping display mode, controlling a pixel electrode to drive the first light-emitting unit of the light-emitting element to emit light;
in response to determining to display in a sharing display mode, controlling the pixel electrode to drive the first light-emitting unit and the second light-emitting unit of the light-emitting element to emit light simultaneously.
